(19) United States
(12) Patent Application Publication
(10) Pub. No.: US 2020/0219861 A1
(43) Pub. Date: Jul. 9, 2020

(54) FRONT END SYSTEM HAVING AN ACOUSTIC WAVE RESONATOR (AWR) ON AN INTERPOSER SUBSTRATE

(71) Applicant: Intel Corporation, Santa Clara, CA (US)

(72) Inventors: Telesphor KAMGAING, Chandler, AZ (US); Vijay K. NAIR, Mesa, AZ (US); Feras EID, Chandler, AZ (US); Georgios C. DOGIAMIS, Chandler, AZ (US); Johanna M. SWAN, Scottsdale, AZ (US); Stephan LEUSCHNER, Munich (DE)

(21) Appl. No.: 16/647,451

(22) PCT Filed: Dec. 28, 2017
(86) PCT No.: PCT/US2017/068754

§ 371 Date: Mar. 13, 2020

(51) Int. Cl. H01L 25/16; H01L 23/498; H01L 23/24; H03H 9/17; H03H 9/05

(52) U.S. Cl. CPC H01L 25/16; H01L 23/49827; H03H 9/0538; H01L 23/49833; H03H 9/171; H01L 23/24

(57) ABSTRACT

RF front end systems or modules with an acoustic wave resonator (AWR) on an interposer substrate are described. In an example, an integrated system includes an active die, the active die comprising a semiconductor substrate having a plurality of active circuits therein. An interposer is also included, the interposer comprising an acoustic wave resonator (AWR). A seal frame couples the active die to the interposer, the seal frame surrounding the acoustic wave resonator and hermetically sealing the acoustic wave resonator between the active die and the interposer.

### TECHNICAL FIELD

Embodiments of the present disclosure relate to RF front end systems and more particularly to an RF front end system or module with an acoustic wave resonator (AWR) on an interposer substrate.

### BACKGROUND

Filters in 4G and 5G front end modules account for up to 50% or more of the total real estate of a system. Several such filters are dedicated to cellular communication and utilize acoustic wave resonators. The acoustic wave resonators on the other hand need to be hermetically sealed to improve reliability while reducing the impact of the environmental conditions on the filter performance. There have been proposals to co-integrate the filters along with active front-end circuits on a same die. This, however, can lead to higher costs as a result of increased die size and low reliability resulting from the attempt to implement a hermetic seal and the resonator on the same active die.

### BRIEF DESCRIPTION OF THE DRAWINGS

FIG. 1 is an illustration of an integrated front end system or module, in accordance with an embodiment of the present disclosure.

FIG. 2 is an illustration of an integrated front end system or module, in accordance with another embodiment of the present disclosure.

FIG. 3 is a schematic illustration of a RF front end system or module in accordance with an embodiment of the present disclosure.

FIG. 4 is a schematic illustration of an RF hybrid circuit or filter in accordance with an embodiment of the present disclosure.

FIG. 5A and FIG. 5B illustrate various capacitors which may be integrated or embedded into a package substrate, in accordance with embodiments of the present disclosure.

FIGS. 6A-6F illustrate various inductors which may be embedded into a package substrate in accordance with embodiments of the present disclosure.

FIG. 7 is a schematic block diagram illustrating a computer system that utilizes an integrated system, as described herein, in accordance with an embodiment of the present disclosure, in accordance with an embodiment of the present disclosure.

### EMBODIMENTS OF THE PRESENT DISCLOSURE

RF front end systems or modules with an acoustic wave resonator (AWR) on an interposer substrate are described. In the following description, numerous specific details are set forth, such as specific material and structural regimes, in order to provide a thorough understanding of embodiments of the present disclosure. It will be apparent to one skilled in the art that embodiments of the present disclosure may be practiced without these specific details. In other instances, well-known features are not described in detail in order to not unnecessarily obscure embodiments of the present disclosure. Furthermore, it is to be understood that the various embodiments shown in the Figures are illustrative representations and are not necessarily drawn to scale. In some cases, various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Certain terminology may also be used in the following description for the purpose of reference only, and thus are not intended to be limiting. For example, terms such as “upper”, “lower”, “above”, “below,” “bottom,” and “top” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

Embodiments of the present disclosure relate to front end systems or modules having an acoustic wave resonator on an interposer substrate. In embodiments of the present disclosure, an integrated front end system includes an active die or main die coupled to an interposer comprising one or more acoustic wave resonators (AWR) (one or more resonators). In an embodiment, the active die or main die includes active RF front end module components, such as transistors, power amplifiers, low noise amplifiers, matching networks, etc. In an embodiment, the active die is attached to the interposer by a seal frame or ring which surrounds the resonator to form a hermetically sealed cavity around the one or more acoustic wave resonators. In this way, the active die may serve as a cap or lid for the resonator disposed in the interposer. In an embodiment, a side of the interposer opposite the active die is attached to a package substrate or main board such as a mother board or daughter board.

In an embodiment, passive components of a filter, such as capacitors, inductors and transformers, may be formed in the interposer and/or the package substrate or main board. Embodiments of the present disclosure allow for the compact integration of different filter components with front end active circuits without having to form and assemble each of these elements separately as discrete components. In an embodiment of the present disclosure, a highly integrated front end module or system which may be utilized in communication systems and networks, such as 5G networks, which require transfer of data at high data rates is realized. Additionally, integrating one or more resonators on an interposer improves yield loss versus integrating everything on a single die and as such may provide cost benefits.

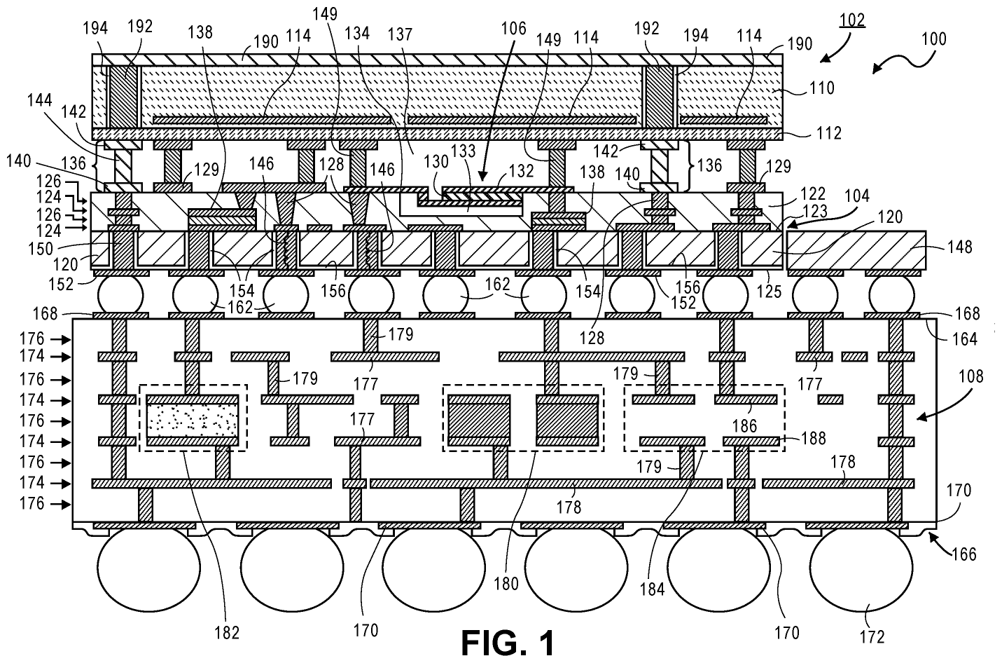

FIG. 1 illustrates an integrated system or module 100 in accordance with embodiments of the present disclosure. Integrated system or module 100 includes an active die or main die 102 coupled to an interposer 104 having an acoustic wave resonator (resonator) 106 disposed therein. In an embodiment, system 100 may include a package substrate 108 or a motherboard, daughter board or main board wherein the interposer is electrically coupled to the package substrate or main board, daughter board or mother board.

In an embodiment, active die 102 includes a semiconductor substrate 110 and an interconnect structure 112, such as a multilevel or multilayer interconnect structure. In an embodiment, substrate 110 may be a semiconductor substrate, such as but not limited to a silicon substrate, a silicon on insulator substrate, a silicon carbide substrate, or a group III-V semiconductor substrate, such as but not limited to gallium nitride (GaN), gallium arsenide (GaAs), and indium phosphide (InP). In an embodiment, semiconductor substrate 110 is a monocrystalline silicon substrate. In another embodiment, semiconductor substrate 110 is a gallium nitride substrate. In an embodiment, a plurality of active devices 114, such as transistors, and/or diodes and/or varactors, are fabricated in or on an active side or front side of substrate 110. In an embodiment, active devices 114 may be electrically coupled together by interconnect structure 112 and passive components on die (not shown) to form a plurality of active circuits used in a radio frequency (RF) front end system, such as but not limited to power amplifiers, low noise amplifiers, tunable matching networks, and switches. In an embodiment, substrate 110 is a silicon substrate and contains CMOS circuitry and transistors such as nonplanar FINFETs. In an embodiment, such FINFETs formed in silicon substrate 110 may be coupled together by interconnect structure 112 to create a processor, such as an application processor. The finFets may also be interconnected to form driver circuits for RF circuits.

Interconnect structure 112 may be disposed on front side of substrate 102. In an embodiment, interconnect structure 112 is a multilayer interconnect structure including multiple metallization layers separated by dielectric layers. Conductive vias may electrically connect one level of metal to another level of metal. Each of the metal layers may contain a plurality of metal interconnects used to route signals and power to various devices and components on active die 102. The metal layers may be formed from any suitable metal or stack of metals, such as but not limited to copper, aluminum, gold, titanium nitride and tantalum nitride. Dielectric layers may be formed from any suitable or dielectric or stack of dielectrics, such as but not limited to polyimide, BCB, silicon oxide, carbon doped silicon, silicon oxynitride and silicon nitride. In an embodiment of the present disclosure, the metal layers and conductive vias may be fabricated by any well known process, such as by a damascene or dual damascene process. In an embodiment, interconnect structure 112 may include passive devices, such as capacitors and/or inductors and/or resistors, disposed therein.

In an embodiment, interposer 104 may include an interposer substrate 120 and an interposer interconnect structure 122 such as a multilayer interconnect structure, disposed on a die side 123 of interposer substrate 120. In an embodiment, interposer substrate 120 may be made of silicon, glass, ceramics, such as alumina or low temperature co-fired ceramic (LTCC), or other hermetic materials. In an embodiment, interposer substrate 120 may be made of a same type of semiconductor, such as silicon or gallium nitride, as active die substrate 110 in order to match the coefficient of thermal expansion of active die 102 and interposer 104.

In an embodiment, interconnect structure 122 may be a multilayer interconnect structure. In an embodiment, interconnect structure 122 is a multilayer interconnect structure including multiple metallization layers 124 separated by dielectric layers 126. Conductive vias 128 may electrically connect to one level of metal 124 to another level of metal 124. Each of the metal layers 124 may contain a plurality of metal interconnects used to route signals and power to various devices and components on interposer 104. The metal layers 124 may be formed from any suitable metal or stack of metals, such as but not limited to copper, aluminum, gold, cobalt, titanium nitride and tantalum nitride. Dielectric layers 126 may be formed from any suitable dielectrics or stack of dielectrics, such as but no limited to silicon oxide, carbon doped silicon oxide, silicon oxynitride and silicon nitride. Although only three metal layers 124 and two dielectric layers 126 are illustrated in FIG. 1, it is to be appreciated that interconnect structure 122 may contain many more metal layers 124 and dielectric layers 120, such as between 6-14 metal layers with corresponding dielectric layers, depending upon the complexity or number of elements or devices to be coupled together. Metal layers 124 and vias 128 of interconnect structure 122 may be fabricated by any well known processes, such as but not limited to damascene and dual damascene processes. In an embodiment, the outermost level of metallization of interconnect structure 112 may include a plurality of contact pads 129 to enable electrical coupling of components formed on or in interposer 104 to active die 102. In an embodiment, interconnect structure 122 may include transmission lines and passive devices, such as capacitors and/or inductors and/or resistors, embedded therein.

In an embodiment, resonator 106 may be disposed in interconnect structure 122 as illustrated in FIG. 1. Resonator 106 may be any well known resonator, such as but not limited to, a bulk acoustic wave (BAW) resonator, a thin film bulk acoustic wave resonator (FBAR), a solidly mounted resonator (SMR), a contour-mode resonator (CMR), a composite longitudinal mode resonator (CLMR) or a surface acoustic wave (SAW) device. In an embodiment of the present disclosure, resonator 106 is a thin film bulk resonator having a piezoelectric material 130 sandwiched between a first electrode 132 and a second electrode 134. The piezoelectric material 130 may be any suitable piezoelectric material, such as but not limited to aluminum nitride, zinc oxide, lead zirconium titanate (PZT), and sodium potassium niobate (KNN), or the like. In an embodiment, the piezoelectric material 130 may have a thickness ranging from several micrometers down to a hundredths of a micrometer. In an embodiment, resonator 106 has a resonance frequency or may resonate at a frequency between 10 MHz to 10 GHz. In an embodiment, resonator 106 extends over cavity 133 disposed in interconnect structure 122 in order to enable resonator 106 to translate between 0.1-3 microns. In an embodiment, resonator 106 may have an x-y size between 50 micron by 50 microns to 500 microns by 500 microns.

In an embodiment, active die 102 is electrically coupled to interposer 104 by contacts 149 such as flip-chip contacts, solder balls, or bumps. In an embodiment, active die 102 is attached to interposer 104 by a seal frame or ring 136. Seal frame or ring 136 completely surrounds resonator 106 and creates a hermetic seal between interposer interconnect structure 122 and interconnect structure 112 of active die 102 as illustrated in FIG. 1. Seal frame 136 forms a hermetic and acoustically sealed air cavity 137 around resonator 106 which protects resonator 106 from environmental conditions and interference. In an embodiment, contacts 149 which electrically couple active die 102 to resonator 106 may be located within cavity 137. Seal frame 136 may be made from a metal, such as but not limited to gold, copper, tin and indium. In other embodiments, seal frame may be made from an insulating material, such as but not limited to a glass frit, a polymer such as a liquid crystal polymer, and an inorganic dielectric. In an embodiment, seal frame 136 may have a thickness between 0.5-10 microns. In an embodiment, seal frame 136 includes a metal frame or ring 140 disposed on an outer surface of interconnect structure 122 and a metal frame or ring 142 on interconnect structure 112. The metal frames or rings 140 and 142 may be directly bonded together by, for example, diffusion bonding or may be bonded together by an intermediate solder layer 144 such as eutectic solder, (e.g., lead bismuth).

Although only a single resonator 106 is illustrated in FIG. 1, it is to be appreciated that interposer 104 may contain two or more resonators 106. In one embodiment, two or more resonators may be located in cavity 137 created by active die 102 and seal frame 136. In another embodiment, interposer 104 may contain two or more resonators 106 and two or more seal frames 136 so that one resonator 106 may be located in one cavity, and a second resonator 106 may be located in a second different cavity.

In an embodiment, one or more capacitors 138 may be disposed in interconnect structure 122 of interposer 104. Capacitors 138 may be any suitable capacitor, such as but not limited to a parallel plate capacitor, a metal insulator metal (MIM) capacitor, an interdigitated capacitor, and/or a cap or trench capacitor. Capacitors may include a capacitor dielectric which may be an organic or inorganic material, such as silica filled epoxy, silicon nitride, silicon oxynitride, barium titanate, titanium oxide, or barium zirconium titanate.

In an embodiment, interposer 104 includes a plurality of through substrate vias (TSVs) 150 which extend through substrate 120 as illustrated in FIG. 1. In an embodiment, TSVs 150 extend from die side 123 of substrate 120 to a backside 125 of substrate 120. In an embodiment, TSVs 150 electrically couple contact pads 152 on backside 125 of substrate 120 to metal layers 124, such as a lower most metal layer 124 of interconnect structure 122. In an embodiment, TSVs 150 may be coupled to diffusion regions formed in substrate 120. TSVs 150 may enable electrical connections to be made to devices and components, and resonator 106 disposed in or on interposer 104 to other components external to interposer 104, such as package substrate 108 or a main board. In an embodiment, when, for example, substrate 120 is fabricated from a low resistance semiconductor, such as low resistance silicon, it may be necessary to line the TSVs 150 with an insulator 154, such as an oxide, in order to electrically isolate the TSVs. Similarly, it may be necessary to form an insulating layer 156, such as an oxide, on the backside 124 of substrate 120 prior to forming contact pads 152 in order to electrically isolate contact pads 152. TSVs 150 may be formed by forming via openings by, for example, drilling, such as laser drilling, or etching, and then filling the openings with an conductive material, such as copper or tungsten. In an embodiment of the present disclosure, backside 125 of interposer substrate 120 may contain one or more redistribution layers in order to route contact pads 152 to TSVs 150 which are not located directly above contact pad 152. In an embodiment, one or more of the TSVs 150 is or includes an inductor 146. In an embodiment, two adjacent vias contain inductors or windings and are inductively coupled to form a transformer. In an embodiment, one or more backside capacitors may be fabricated in the redistribution layer or layers. In this way, the backside capacitors may be located closer to passive devices disposed or embedded in package substrate 108 as described below.

In an embodiment, interposer 104 is electrically coupled to a package substrate or main board 108, as illustrated in FIG. 1. In an embodiment, an assembly comprising active die 102 and interposer 104 is electrically coupled by contacts 162 to package substrate 108. In an embodiment, a wafer-level process is used to form the assembly. In such an embodiment, a plurality of active dies 102 may be fabricated on a first wafer or substrate. Similarly, a plurality of interposers 104 may be fabricated on a second wafer or substrate. The first and second wafers or substrates are then bonded together by for example corresponding seal frames or rings 136 and contacts 149. Wafer dicing may then be used to singulate the coupled wafers or substrates into individual assemblies comprising an active die 102 and an interposer 104. An individual assembly may be coupled to a package substrate or a main board, such as mother board or daughter board, etc.

In an embodiment, package substrate 108 has an interposer side 164 and a land side or second level interconnect (SLI) side 166. A plurality of contact pads 168 are disposed on interposer side 164. In an embodiment, solder balls 162 electrically couple contact pads 152 on interposer 104 to corresponding contact pads 168 on package substrate 108 as illustrated in FIG. 1. Land side 166 of package substrate 108 includes a plurality of contact pads or land pads 170. A plurality of second level contacts, such as solder balls or bumps 172 may be disposed on pads 170 to enable integrated system 100 to be electrically coupled to other components, such as a mother board or main board. In an embodiment, contact pads 168 have a tighter pitch and are smaller than the pitch and size of contacts pads 170, as is depicted.

Package substrate 108 may be any suitable package substrate. In an embodiment, package substrate 108 is an organic multilayer printed circuit board. In an embodiment, package substrate 108 is an organic package substrate including polyimide or epoxy insulating layers and copper metal layers. In another embodiment, package substrate 108 is an inorganic package substrate such as a ceramic substrate, such as a low temperature co-fired ceramic substrate or a high temperature co-fired ceramic substrate, a glass substrate (e.g., silicon oxide), or a semiconductor substrate (e.g., silicon). In an embodiment, package substrate 108 is a multilayer package substrate which includes a plurality of metallization layers 174 each comprising a plurality of electrical traces 177 or power planes 178. Each metallization layer 174 may be separated from adjacent metal layers 174 by one or more dielectric layers 176. Conductive vias 179 may be disposed in the dielectric layers 176 to enable electrical connections from one metallization layer to another.

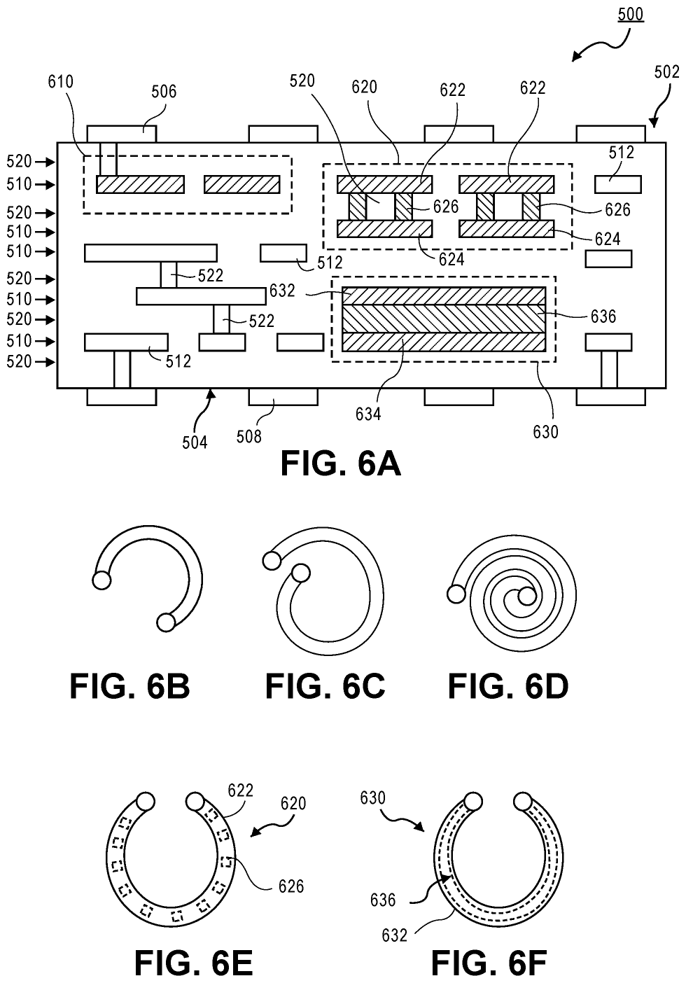

In an embodiment, package substrate 108 includes one or more inductors 180 embedded therein as illustrated in FIG. 1. Inductor 180 may be a partial loop inductor, a single loop inductor, or a multi loop inductor fabricated in a single level or multiple levels of package substrate 108 as described in more detail with respect to FIGS. 6A-6F. In an embodiment, inductor 180 may consist of one or more turns of conductive material, such as copper, separated by a dielectric such as a polymer, a ceramic, a glass, or air. In one embodiment, the one or more turns of conductive material are separated by the material of package substrate 108. In an embodiment, inductor 180 is electrically coupled by an electrical connection to resonator 106 of integrated system 100.

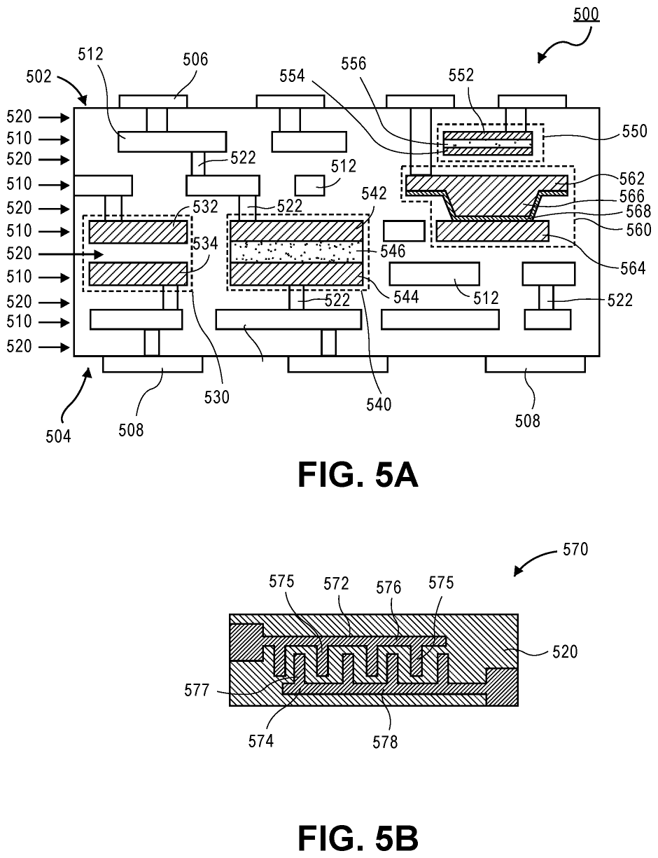

In an embodiment, package substrate 108 may include one or more capacitors 182 embedded therein. Capacitor 182 may be a parallel plate capacitor or interdigitated capacitor and may be fabricated in a single layer 174 or multiple layers of package substrate 160 as described in more detail with respect to FIGS. 5A and 5B. In an embodiment, capacitor 182 may be electrically coupled by an electrical connection to resonator 106 of integrated system 100. In an embodiment, capacitor 182 may be electrically coupled by an electrical connection to inductor 180. In an embodiment of the present disclosure, inductor 180 may be part of a network of inductors including a transformer equivalent circuit, such as a Pi-network or T-network. In an embodiment of the present disclosure, integrated system 100 may contain passive devices, acoustic wave resonators and couplings thereto to create a hybrid filter, such as hybrid filter 400 described below.

In an embodiment of the present disclosure, package substrate 108 includes one or more transformers 184 embedded therein. In an embodiment, transformer 184 includes a first winding 186 and a second winding 188 wherein the first winding 186 and the second winding 188 are inductively coupled. In an embodiment, first winding 186 is vertically above second winding 188 as illustrated in FIG. 1. In an embodiment, first winding 186 and second winding 188 are substantially aligned with one another. In another embodiment, first winding 186 has a central axis which is slightly offset from a central axis of second winding 188 in order to control the coupling coefficient of transformer 184. In an embodiment, first winding 186 is a planar winding fabricated in a single layer 174 of package substrate 108, and second winding 188 is a planar winding fabricated in a single different metal layer 174 of package substrate 108. In an embodiment, first winding 186 is separated from second winding 188 by a vertical distance of between 15 microns to 60 microns. In an embodiment, first winding 186 and second winding 188 may each be fabricated in multiple metal layers 174 of package substrate 108 in order to create high quality factor (high Q) inductors for transformer 184. In an embodiment, first winding 186 may be electrically coupled to capacitor 182 embedded within package substrate 108. In an embodiment, second winding 188 is electrically coupled to another capacitor 182 embedded in package substrate 108. In an embodiment, transformer 184 may be a vertical transformer where first winding 186 and second winding 188 are fabricated in multiple metal layers 174 of package substrate 108. In an embodiment, first winding 186 and second winding 188 may be interleaved with one another. In an embodiment, the vertical transformer has an implementation with angle offset with mutual coupling adjustment. In an embodiment, package substrate 108 may include one or more discrete inductors and/or one or more discrete capacitors (as represented by passive component 148) attached to the interposer side 164 of package substrate 108. In an embodiment, one or more antennas may be included in package substrate 108.

In an embodiment, active die 102 may include a metal plate or shield 190 disposed on the backside of substrate 110 to provide electromagnetic interference shielding for components disposed within the active die 102. In an embodiment, metal plate or shield 190 is grounded. In an embodiment, one or more through substrate vias 192 may be disposed through semiconductor substrate 110 and electrically couple metal plate or shield 190 to interconnect structure 112. In an embodiment, metal seal frame 136 is electrically coupled through interconnect structure 112 to substrate vias 192 to couple the metal plate or shield 190 through the interposer 104 to a ground plane 178 of package substrate 108. Through substrate vias 192 may include a dielectric 194 to insulate the through substrate vias 192.

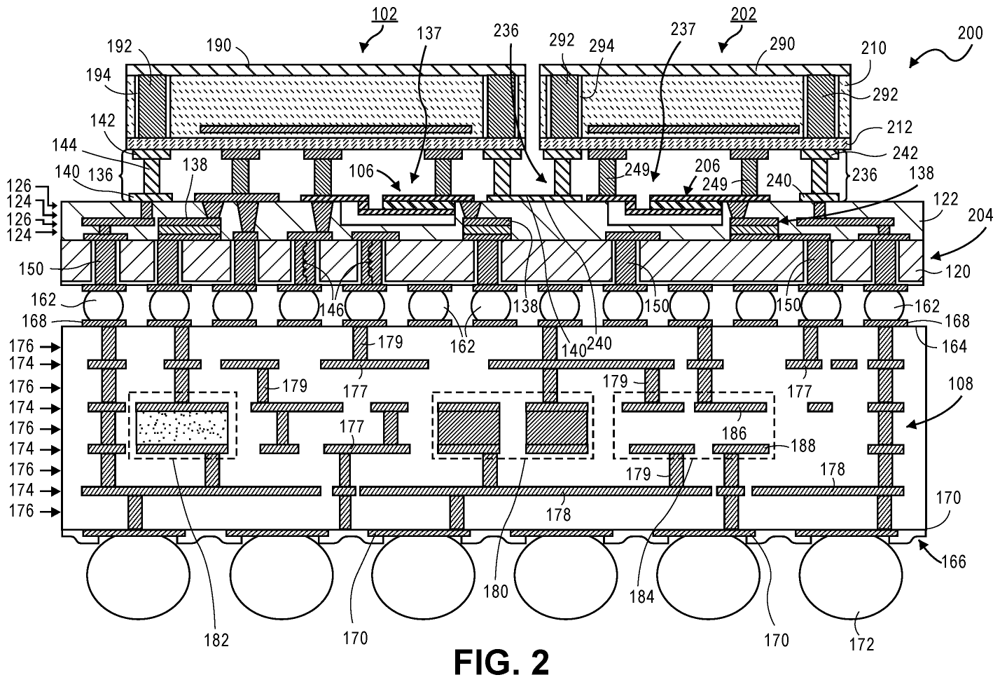

FIG. 2 is an illustration of an integrated system or module 200 in accordance with an embodiment of the present disclosure. System 200 is similar to system 100 but includes a second active or main die 202. Active die 202 may be similar to active die 102 as discussed above. System 200 includes an interposer 204 which is similar to interposer 104 except that it includes an additional resonator (or multiple additional resonators) 206 that may be similar to resonator 106. Interposer 204 may be coupled to a package substrate, such as package substrate 108 illustrated in FIG. 2. In an embodiment, active die 202 is positioned over resonator 206 as illustrated in FIG. 2. In an embodiment, active die 202 is electrically coupled to interposer 104 by contacts 249 such as flip-chip contacts, solder balls, or bumps. Active die 202 may be attached to interposer 204 by a seal frame or ring 236 which may be similar to seal frame or ring 136. Seal frame or ring 236 completely surrounds resonator 206 and creates a hermetic seal between interposer 204 and active die 202 as illustrated in FIG. 2. Seal frame 236 may form a hermetic and acoustically sealed air cavity 237 around resonator 206 which protects resonator 206 from environmental conditions and interference. In an embodiment, contacts 249 which electrically couple active die 202 to resonator 206 may be located within cavity 237. In an embodiment, seal frame 236 may contain a metal frame or metal ring portion 240 on interconnect structure 122 and a metal frame or ring portion 242 formed on interconect structure 112. In an embodiment, metal frame or metal ring portion 240 shares a common wall with metal frame or ring portion 140 of seal frame or ring 136 formed on interconnect structure 122 as illustrated in FIG. 2.

In an embodiment, active die 102 and active die 202 may represent various Transmit and Receive bands. For example, active die 102 may have all of the circuits required for a 4.4 GHz transmit module while active die 202 may have all of the circuits required for a 4.4 GHz receive module. Filters, such as hybrid filters described below, for both transmission and receiving bands may be integrated in the interposer 204 and package substrate 108. In an embodiment, active die 102 and active die 202 may be fabricated from different technologies or substrates. For example, in an embodiment, active die 102 may comprise a silicon substrate and contain CMOS circuitry while active die 202 may comprise a gallium nitride substrate and contain RF circuitry. In another embodiment, one of the two dies is not an active die in that it does not include active circuits. For example, die 102 may be a passive only cap die. In an embodiment, since active circuits may occupy less area than the filters, it may be economical to cap the resonator with a cap that is not an active die cap.

Although only a single resonator 206 is illustrated beneath active die 202 in FIG. 2, it is to be appreciated that two or more resonators 206 may be included in cavity 237 created by active die 202 and seal frame or ring 236 and interposer 204. In one embodiment, two or more resonators may be located in cavity 237 created by active die 202 and seal frame 236. In an embodiment, resonator 206 has a resonance frequency different than a resonance frequency of resonator 106.

In an embodiment, active die 202 may include a metal plate or shield 290 disposed on the backside of substrate 210 of active die 202 to provide electromagnetic interference shielding for components disposed within the active die 202. In an embodiment, metal plate or shield 290 is grounded. In an embodiment, one or more through substrate vias 292 may be disposed through semiconductor substrate 210 and electrically couple metal plate or shield 290 to interconnect structure 212. In an embodiment, metal seal frame 236 is electrically coupled through interconnect structure 212 to substrate vias 292 to couple the metal plate or shield 290 through the interposer 104 to a ground plane 178 of package substrate 108. Through substrate vias 292 may include an oxide 294 to insulate the through substrate vias 292.

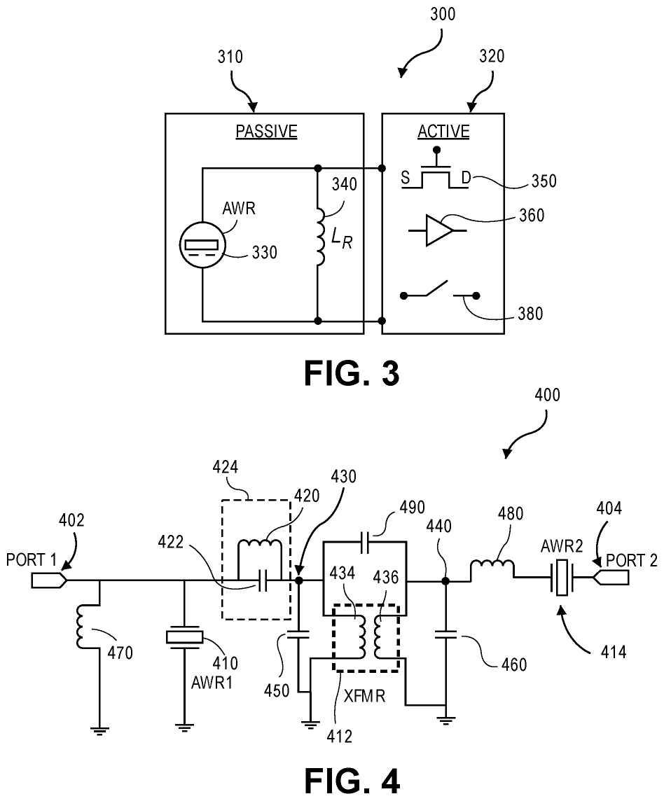

FIG. 3 is a schematic illustration of an RF front end system or module 300 which may be included in integrated system 100 or 200, described above. RF module 300 includes passive devices 310 and active devices and circuits 320. Passive devices 310 may include an acoustic wave resonator 330 and an inductor 340 coupled together in parallel. The active devices and circuits 320 may include transistors 350, amplifiers 360 and switches 380. In an embodiment, passive devices 310 may be coupled together to form a filter or bank of filters or a hybrid filter or bank of hybrid filters. In an embodiment, passive devices 310 are coupled together to form a hybrid filter such as described below in association with FIG. 4. In an embodiment, the passive devices 310 and active devices or circuits 320 are integrated together in an integrated system including an active die, an interposer and a package substrate, as described above.

Embodiments of the present disclosure relate to hybrid filters and more particularly to filters having acoustic wave resonators (AWRs) and transformers and packages therefor, and integrated systems containing them. Embodiments of the present disclosure relate to a radio frequency (RF) hybrid filter having a plurality of acoustic wave resonators (AWR) and a transformer based resonator. The basic principle of the embodiments of the present disclosure consist of utilizing at least one RF transformer as the core of an LC resonator and one or more acoustic wave resonators to improve the out of band rejection of the resulting hybrid filter. The use of a transformer reduces the number of components in the filter. Additionally, the broadband nature of a transformer results in low parasitics and therefore enables filters operating at high frequencies. The filter can be further implemented by using an equivalent circuit of a transformer, such as a T-network or a Pi-network. In an embodiment, the hybrid circuit includes multiple parallel acoustic wave resonators to enhance the signal rejection in the guard band and at the band edge. The hybrid filter of the present disclosure may exhibit wide bandwidth and sharp roll off. The hybrid filter of the present disclosure may be used in next generation mobile and wireless communication devices and infrastructures which require the handling of data at high rates, such as 5G networks. In embodiments, the filters of the present disclosure may exhibit excellent roll off and out of band rejection to enable multi-radio coexistence.

In embodiments of the present disclosure the hybrid filter is a hybrid LC/AWR (lumped component/acoustic wave resonator) filter comprising RF passive elements, such as inductors, transformers and capacitors, and acoustic wave resonators fabricated using a piezoelectric material, such as a thin film bulk acoustic resonator (FBAR to TFBAR). In an embodiment, a first winding of a transformer may be coupled to a first port and to a first acoustic wave resonator and a second acoustic wave resonator may be coupled to a second winding of the transformer and to a second port. A first capacitor may be coupled in parallel with the first winding of the inductor and a second capacitor may be coupled in parallel with a second winding of the transformer. A lumped element resonator comprising an inductor coupled in parallel with a capacitor may be disposed between the coupling of the first acoustic wave resonator and the first winding of the transformer.

FIG. 4 is a schematic illustration of an RF hybrid circuit or filter 400 in accordance with an embodiment of the present disclosure. Hybrid filter 400 includes a first acoustic wave resonator (AWR) 410, a lumped element resonator 424, a transformer 412 and a second acoustic wave resonator (AWR) 414. In an embodiment, first AWR 410 has a first electrode coupled to a first port or an input port 402 and has a second electrode coupled to ground. In an embodiment, an inductor 420 has a first terminal coupled to the first electrode of AWR 410 and to the input port 402 and a second terminal coupled to a first node 430. A capacitor 422 is coupled in parallel with inductor 420. The capacitor 422 and the inductor 420 create a lump element resonator 424 which forms a transmission zero either below or above the pass band region. A first coil or winding 434 of transformer 412 has a first terminal coupled to node 430 and a second terminal couple to ground. A second coil or winding 436 of transformer 412 has a first terminal coupled to a node 440 and a second terminal coupled to ground as illustrated in FIG. 4. A capacitor 450 has a first electrode or plate coupled to node 430 and in an embodiment a second electrode or plate coupled to ground. In an embodiment the second electrode of capacitor 450 is directly connected to the second terminal of first winding 434 of transformer 412. A capacitor 460 has a first electrode or plate coupled to node 440 and in an embodiment has a second electrode or plate coupled to ground. In an embodiment, the second electrode of capacitor 460 is directly connected to the second terminal of the second winding 436 of transformer 412. Although each of the second terminals of capacitor 450 and capacitor 460 are illustrated as being coupled to ground, they may each be, in an embodiment, connected to a same or different DC voltage in order to provide tuning capabilities. The poles of the filter are defined by capacitors 450 and 460 and transformer 412. In an embodiment, filter 400 has two poles and therefore may be considered a second order filter.

Second AWR 414 has a first electrode coupled to node 440 and a second electrode coupled to a second port or output port 404. In an embodiment, hybrid filter 400 of FIG. 4 includes two acoustic wave resonators, AWR 410 and AWR 414. The acoustic wave resonators act as a transmission zero around the edge of the passband and therefore enable filter 400 to achieve strong rejection in the adjacent guard band.

In an embodiment, filter 400 may include one or more matching inductors. In an embodiment, filter 400 includes an inductor 470 having a first terminal coupled to input port 402 and a second terminal coupled to ground. In an embodiment, filter 400 may include an inductor 480 disposed between second AWR 414 and node 440. In an embodiment, inductor 480 has a first terminal coupled to node 440 and a second terminal to the first electrode of AWR 414, as illustrated in FIG. 4. In an embodiment, inductor 470 and inductor 480 are matching inductors and act as transmission zero (responsible for signal attenuation) at low and high frequencies, respectively.

In an embodiment, filter 400 may include a capacitor 490 having a first electrode or plate coupled to node 430 and a second electrode or plate coupled to node 440, as illustrated in FIG. 4. Capacitor 490 may form another transmission zero with transformer 412.

In embodiments of the present disclosure, individual ones of the inductors 420, 470, and 480 may be implemented as a series combination of two or more smaller inductors to improve the frequency range of operation at a cost of induction density and/or quality factor. Similarly, individual ones of the capacitors 422, 450, 460 and 490 may be implemented as a parallel combination of two or more smaller capacitors. In an embodiment, the inductors may have an inductance in the range of 0.1 to 15 nanohenrys. In an embodiment, the capacitors may have a capacitance in the range of 0.1 to 15 picofarads.

First winding 434 and second winding 436 of transformer 412 may be inductively coupled together. That is, first winding 434 and second winding 436 may be sufficiently close together to provide mutual inductive coupling. In an embodiment, first winding 434 and second winding 436 have a low inductive mutual coupling coefficient of between 0.01 to 0.5. In an embodiment, first winding 434 and second winding 436 are sufficiently sized to create an inductance ratio between 1:2-2:1. In an embodiment first winding 434 and second winding 436 have an inductance ratio of approximately 1:1. First winding 434 may be considered the primary coil of transformer 412 and second winding 436 may be considered the secondary winding of transformer 412. In an embodiment, transformer 412 may be replaced with a transformer equivalent circuit such as a T-network of inductors or a Pi-network of inductors.

In an embodiment, hybrid filter 400 is a RF through band pass filter. Filter 400 may reject signals at both low and high frequencies. The signal transmission between input port 402 and output port 404 is maximum in the desired passband region. In an embodiment, an RF analog input signal having a frequency between 800 MHz to 8 GHz is applied to input port 402. In an embodiment, an analog signal between 3.3 to 4.2 GHz is provided to input port 402. In yet another embodiment, an input signal between 4.4 to 4.9 GHz is provided to input port 402. The input signal passes through filter 400 and a filtered analog output signal is provided on output port 404.

FIG. 5A and FIG. 5B illustrate various capacitors which may be integrated or embedded into a package substrate, an interposer, and/or an active die, in accordance with embodiments of the present disclosure. In embodiments, capacitors are thin film resonators consisting of metal electrodes and a low loss tangent dielectric material between the electrodes. The quality of the capacitors increases with decreasing loss tangent of the dielectric material. The capacitor dielectric material may have a high dielectric constant to reduce the footprint of the capacitor. FIG. 5A is a cross sectional illustration of a multilayer package substrate 500, such as a multilayer organic package substrate or a low temperature co-fired substrate. Substrate 500 includes a first side 502 and a second side 504 opposite the first side 502. A plurality of contact pads 506 may be disposed on first side 502 and a plurality of contact pads 508 may be disposed on second side 504. Multilayer substrate 500 includes a plurality of metal layers 510, such as copper layers. Each of the metal layers 510 includes a plurality of metal traces or conductors 512. A plurality of dielectric layers 520, such as silicon dioxide or silicon oxide layers, are disposed between metal layers 510 to electrically isolate the metal layers 510 from one another. Dielectric layers 520 may also be disposed between traces 512 of metal layers 510. A plurality of conductive vias 522, such as copper vias, may be disposed in dielectric layers 520 to enable electrical connections between adjacent metal layers 510.

In an embodiment, package substrate 500 may include a parallel plate capacitor 530 which includes a first electrode or plate 532 formed in one metal layer 510 and a second electrode or plate 534 formed in a second vertically adjacent metal layer 510. In an embodiment, a portion of the dielectric layers 520 between first electrode or plate 532 and second electrode or plate 534 forms the capacitor dielectric layer of capacitor 530.

In an embodiment, package substrate 500 may include one or more parallel plate capacitors 540 which includes a first electrode or plate 542 formed in one metal layer 510 and a second electrode or plate 544 disposed in a second vertically adjacent metal layer 510. Capacitor 540 may include a capacitor dielectric 546 formed of a dielectric material which is different than the dielectric material 520 used to isolate the metal layers 510 of package substrate 500. In an embodiment, dielectric 546 is a high dielectric constant material, such as a metal oxide dielectric material, e.g., aluminum oxide, zirconium oxide, hafnium oxide, BST or PZT. In an embodiment, dielectric 546 is a low loss tangent dielectric material. In this way, a high performance capacitor may be fabricated.

In an embodiment, package substrate 500 may include one or more parallel plate capacitors 550. Capacitor 550 includes a first electrode or plate 552, a second electrode or plate 554 and an intervening capacitor dielectric 556 disposed there between. In an embodiment, capacitor 550 is disposed in a single metal layer 510 of substrate 500 as illustrated in FIG. 5A. In an embodiment, capacitor dielectric 556 may be formed from a dielectric material having a high dielectric constant, such as a high k dielectric and which is different than the dielectric material 520 used to form package substrate 500. In an embodiment, dielectric 556 is a high dielectric constant material, such as a metal oxide dielectric material, e.g., aluminum oxide, zirconium oxide, hafnium oxide, BST or PZT. In an embodiment, dielectric 556 is a low loss tangent dielectric material. In this way, a high performance capacitor may be fabricated.

In an embodiment, package substrate 500 may include one or more capacitors 560 as illustrated in FIG. 5A. Capacitor 560 includes a top electrode 562 and a bottom electrode 564. Top electrode 562 includes a via portion 566. Via portion 566 is separated from bottom electrode 564 by a capacitor dielectric 568. Capacitor dielectric 568 may be deposited in a via opening prior to filling the via with a conductive material, such as copper. In an embodiment, capacitor dielectric 568 is a high k dielectric layer, such as a metal oxide, such as hafnium oxide or aluminum oxide. In an embodiment, capacitor dielectric 568 is a low loss dielectric material. In an embodiment, capacitor dielectric 568 is a different dielectric material than dielectric material 520. In an embodiment, capacitor dielectric 568 is a high dielectric constant material, such as a metal oxide dielectric material, e.g., aluminum oxide, zirconium oxide, hafnium oxide, BST or PZT. In an embodiment, capacitor dielectric 568 is a low loss tangent dielectric material. In this way, a high performance capacitor may be fabricated.

FIG. 5B illustrates a plan view of a capacitor 570 which may be embedded in package substrate 500 in accordance with embodiments of the present disclosure. Capacitor 570 includes a first electrode 572 and a second electrode 574. First electrode 572 includes a plurality of fingers 575 extending from a back bone 576 which are interleaved or interdigitated with a plurality of fingers 577 extending from a back bone 578 of second electrode 574 as illustrated in FIG. 5B. In an embodiment, first electrode 572 and second electrode 574 are disposed in a same metal layer 510 or plane of package substrate 500. Dielectric layer 520 disposed between the back bone and fingers of the electrodes may act as a capacitor dielectric. In an embodiment, dielectric material 520 disposed between the electrodes may be replaced with a different dielectric material, such as a high k dielectric material and/or a low loss tangent dielectric material, if desired.

Although capacitors 530, 540, 550 and 560 are disclosed as being embedded in a multi-layer package substrate, it is to be appreciated that similar capacitors and techniques may be embedded in the interconnect structure 112 of active die 102 and/or in the interconnect structure 122 of interposer 104.

FIGS. 6A-6F illustrate various inductors which may be embedded into a package substrate, interposer, and/or active die, in accordance with embodiments of the present disclosure. FIG. 6A is a cross-sectional illustration of package substrate 500 which in an embodiment may include one or more inductors formed from one or more metal layers 510 of package substrate 500. In an embodiment, package substrate 500 may include one or more inductors 610. In an embodiment, inductor 610 has a loop disposed in a single metal layer 510 of package substrate 500. Inductor 610 may have a partial or fractional loop, as illustrated in FIG. 6B, a full loop, as illustrated in FIG. 6C, or multiple loops, such as two or more loops as illustrated in FIG. 6D.

In an embodiment, package substrate 500 may include one or more inductors 620. Inductor 620 may include one or more loops including a first metal portion 622 disposed in a first metal layer 510 of package substrate 500 and a second metal portion 624 disposed in a second metal layer 510 vertically adjacent to the first metal layer 510. The first metal portion 622 is electrically coupled to the second metal portion 624 by a plurality of metal vias 626, as illustrated in FIG. 6A. In this way, an inductor 620 may have a loop with a metal thickness greater than the metal thickness of a single metal layer 510 of package substrate 500 and thereby yield a high Q inductor. By increasing the thickness of the conductors of inductor 620, an inductor having a Q factor of 100 or better at the frequency of operation may be achieved.

FIG. 6E is a plan view of inductor 620 showing a top portion 622 of a loop and the underlying vias 626 electrically connected thereto. Dielectric material 520 may be disposed between conductive vias 626 and between the first metal portion 622 and a second metal portion 624. If desired, inductor 620 may include a third metal portion disposed in a third metal layer 510 and be electrically connected to second metal portion 624 by a second plurality of conductive vias. In an embodiment of the present disclosure, the plurality of conductive vias 626 and 522 may be formed by laser drilling a plurality of via openings in the dielectric layer 510 and then filling the vias with a conductive material, such as copper, when forming the metal layer 510 above. Laser drilling provides a cost effective method of creating vias 626 and 522.

In an embodiment, package substrate 500 may include one or more inductors 630 as illustrated in FIG. 6A. Inductor 630 includes a first metal portion 632 disposed in a first metal layer 510 and a second metal portion 634 disposed in a second metal layer 510 vertically adjacent to the first metal layer 510. A slot via or trench via 636 may be used to connect first metal portion 632 with second metal portion 634. Trench via 634 may have a length substantially equal to, or at least 90% of, the length of the loop or loops included in metal portions 632 and 634, as illustrated in FIG. 6F. In an embodiment, trench via 636 has a width which is less than the width of metal portions 632 and 634. Trench vias 636 may be formed by lithographically patterning a trench opening in dielectric layer 520 by, for example, lithographically patterning a photoresist mask and then etching a trench opening in alignment with the photoresist mask. Alternatively, dielectric layer 520 may be a photo definable dielectric and may be directly photo defined to form a trench opening therein. The trench opening may be subsequently filled when forming metal layer 510 which includes metal portion 632. Inductor 630 may be able to exhibit a higher Q factor than inductor 622 because inductor 630 has a trench via which substantially or completely connects the metal portion 632 with the metal portion 634 while inductor 620 is coupled by vias and has dielectric 520 between metal portions 622 and 624, as illustrated in FIG. 6E.

It is to be appreciated that inductors such as inductors 610, 620 and 630 may be stand-alone inductors or may be combined with other inductors to fabricate windings of a transformer or a transformer-equivalent circuit. Although inductors 610, 620 and 630 are disclosed as being embedded in a multi-layer package substrate, it is to be appreciated that similar inductors and techniques may be embedded in the interconnect structure 112 of active die 102 and/or in the interconnect structure 122 of interposer 104.

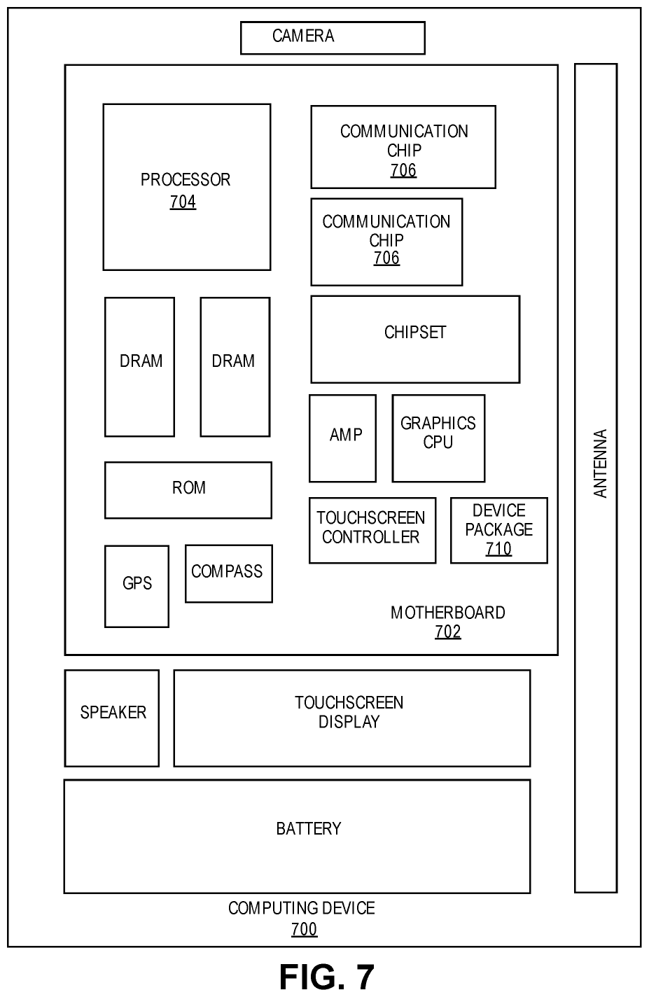

FIG. 7 is a schematic block diagram illustrating a computer system that utilizes an integrated system, as described herein, in accordance with an embodiment of the present disclosure. FIG. 7 illustrates an example of a computing device 700. Computing device 700 houses motherboard 702. Motherboard 702 may include a number of components, including but not limited to processor 704, device package 710, and at least one communication chip 706. Processor 704 is physically and electrically coupled to motherboard 702. For some embodiments, at least one communication chip 706 is also physically and electrically coupled to motherboard 702. For other embodiments, at least one communication chip 706 is part of processor 704.

Depending on its applications, computing device 700 may include other components that may or may not be physically and electrically coupled to motherboard 702. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

At least one communication chip 706 enables wireless communications for the transfer of data to and from computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. At least one communication chip 706 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Computing device 700 may include a plurality of communication chips 706. For instance, a first communication chip 706 may be dedicated to shorter range wireless communications such as Wi-Fi and Bluetooth and a second communication chip 706 may be dedicated to longer range wireless communications such as GPS, EDGE, GPRS, CDMA, WiMAX, LTE, Ev-DO, and others.

Processor 704 of computing device 700 includes an integrated circuit die packaged within processor 704. Device package 710 may be, but is not limited to, a packaging substrate and/or a printed circuit board. Note that device package 710 may be a single component, a subset of components, and/or an entire system.

For some embodiments, the integrated circuit die may be packaged with one or more devices on device package 710 that include a thermally stable RFIC and antenna for use with wireless communications. The term “processor” may refer to any device or portion of a device that processes electronic data from registers and/or memory to transform that electronic data into other electronic data that may be stored in registers and/or memory.

At least one communication chip 706 also includes an integrated circuit die packaged within the communication chip 706. For some embodiments, the integrated circuit die of the communication chip may be packaged with one or more devices on the device package 710, as described herein.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of the present disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of the present application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

The following examples pertain to further embodiments. The various features of the different embodiments may be variously combined with some features included and others excluded to suit a variety of different applications.

Example embodiment 1: An integrated system includes an active die, the active die comprising a semiconductor substrate having a plurality of active circuits therein. The integrated system also includes an interposer, the interposer comprising an acoustic wave resonator (AWR). A seal frame couples the active die to the interposer, the seal frame surrounding the acoustic wave resonator and hermetically sealing the acoustic wave resonator between the active die and the interposer.

Example embodiment 2: The integrated system of example embodiment 1 wherein the seal frame comprises a metal layer selected from the group consisting of gold, copper, tin and indium.

Example embodiment 3: The integrated system of example embodiment 1 wherein the seal frame comprises a material selected from the group consisting of a glass frit and a polymer.

Example embodiment 4: The integrated system of example embodiment 3 wherein the seal frame is a polymer and wherein the polymer is a liquid crystal polymer.

Example embodiment 5: The integrated system of example embodiment 1, 2, 3 or 4 wherein the interposer comprises a capacitor.

Example embodiment 6: The integrated system of example embodiment 1, 2, 3, 4 or 5 wherein the interposer comprises transmission lines and resistors.

Example embodiment 7: The integrated system of example embodiment 1, 2, 3, 4, 5 or 6 wherein the interposer further comprises a plurality of through substrate vias.

Example embodiment 8: The integrated system of example embodiment 7 further comprising an inductor disposed in one of the plurality of through substrate vias.

Example embodiment 9: The integrated system of example embodiment 7 further comprising a transformer disposed in a first and a second through substrate via of the plurality of through substrate vias.

Example embodiment 10: The integrated system of example embodiment 1, 2, 3, 4, 5, 6, 7, 8 or 9 wherein the interposer comprises an interposer substrate and a multilayer interconnect structure on the interposer substrate.

Example embodiment 11: The integrated system of example embodiment 10 wherein the interposer substrate is selected from the group consisting of a silicon substrate, a glass substrate and a ceramic substrate.

Example embodiment 12: The integrated system of example embodiment 10 wherein a capacitor is disposed in the multilayer interconnect structure of the interposer and wherein the capacitor is a metal-insulator-metal capacitor.

Example embodiment 13: The integrated system of example embodiment 1, 2, 3, 4, 5, 6, 7, 8, 9, 10, 11 or 12 wherein the semiconductor substrate is selected from the group consisting of a silicon substrate, a group III-V substrate, and a silicon-on-insulator substrate.

Example embodiment 14: The integrated system of example embodiment 1, 2, 3, 4, 5, 6, 7, 8, 9, 10, 11, 12 or 13 wherein an active circuit of the plurality of active circuits is selected from the group consisting of a power amplifier, a low noise amplifier, a matching network, and a switch.

Example embodiment 15: An integrated system includes an active die, the active die comprising a semiconductor substrate, the active die comprising a plurality of active circuits. The integrated system also includes an interposer, having a die side and a package substrate side, the die side opposite the package substrate side, the active die electrically coupled to the die side of the interposer, the interposer comprising an acoustic wave resonator (AWR). The integrated system also includes a package substrate, the package substrate having an interposer side and a land side opposite the interposer side, the interposer side of the package substrate electrically coupled to the interposer.

Example embodiment 16: The integrated system of example embodiment 15 further comprising a seal frame attached to the die side of the package substrate and to the active die, the seal frame surrounding the acoustic wave resonator and hermetically sealing the acoustic wave resonator in a cavity.

Example embodiment 17: The integrated system of example embodiment 15 or 16 further comprising a plurality of solder balls on the land side of the package substrate.

Example embodiment 18: The integrated system of example embodiment 15, 16 or 17 wherein the package substrate is a multilayer package substrate, and wherein an inductor is disposed in the multilayer package substrate.

Example embodiment 19: The integrated system of example embodiment 15, 16, 17 or 18 wherein the package substrate is a multilayer package substrate, and wherein a transformer is disposed in the multilayer package substrate.

Example embodiment 20: The integrated system of example embodiment 15, 16, 17, 18 or 19 further comprising one of a discrete inductor or a discrete capacitor attached to the package substrate.

Example embodiment 21: An integrated system includes a first active die, the first active die comprising a first semiconductor substrate, the first active die comprising a plurality of first active circuits. The integrated system also includes a second active die, the second active die comprising a second semiconductor substrate, the second active die comprising a plurality of second active circuits. The integrated system also includes an interposer comprising a first acoustic wave resonator (AWR) and a second acoustic wave resonator (AWR) wherein the first active die is disposed over and electrically coupled to the first acoustic wave resonator and wherein the second active die is over and electrically coupled to the second acoustic wave resonator.

Example embodiment 22: The integrated system of example embodiment 21 wherein the first semiconductor substrate is a different semiconductor than the second semiconductor substrate.

Example embodiment 23: The integrated system of example embodiment 21 or 22 wherein the first active die comprises a receiver and wherein the second active die comprise a transmitter.

Example embodiment 24: The integrated system of example embodiment 21, 22 or 23 wherein a first seal frame attaches the first active die to the interposer, the first seal frame surrounding the first acoustic wave resonator and hermetically sealing the first acoustic wave resonator between the first active die and the interposer; and a second seal frame attaches the second active die to the interposer, the second seal frame surrounding the second acoustic wave resonator and hermetically sealing the second acoustic wave resonator between the second active die and the interposer.

Example embodiment 25: The integrated system of example embodiment 21, 22, 23 or 24 further comprising a first electromagnetic shield disposed on the first active die and a second electromagnetic shield disposed on the second active die.

What is claimed is:

1. An integrated system comprising:
an active die, the active die comprising a semiconductor substrate having a plurality of active circuits therein;
an interposer, the interposer comprising an acoustic wave resonator (AWR); and
a seal frame coupling the active die to the interposer, the seal frame surrounding the acoustic wave resonator and hermetically sealing the acoustic wave resonator between the active die and the interposer.

2. The integrated system of claim 1 wherein the seal frame comprises a metal layer selected from the group consisting of gold, copper, tin and indium.

3. The integrated system of claim 1 wherein the seal frame comprises a material selected from the group consisting of a glass frit and a polymer.

4. The integrated system of claim 3 wherein the seal frame is a polymer and wherein the polymer is a liquid crystal polymer.

5. The integrated system of claim 1 wherein the interposer comprises a capacitor.

6. The integrated system of claim 1 wherein the interposer comprises transmission lines and resistors.

7. The integrated system of claim 1 wherein the interposer further comprises a plurality of through substrate vias.

8. The integrated system of claim 7 further comprising an inductor disposed in one of the plurality of through substrate vias.

9. The integrated system of claim 7 further comprising a transformer disposed in a first and a second through substrate via of the plurality of through substrate vias.

10. The integrated system of claim 1 wherein the interposer comprises an interposer substrate and a multilayer interconnect structure on the interposer substrate.

11. The integrated system of claim 10 wherein the interposer substrate is selected from the group consisting of a silicon substrate, a glass substrate and a ceramic substrate.

12. The integrated system of claim 10 wherein a capacitor is disposed in the multilayer interconnect structure of the interposer and wherein the capacitor is a metal-insulator-metal capacitor.

13. The integrated system of claim 1 wherein the semiconductor substrate is selected from the group consisting of a silicon substrate, a group III-V substrate, and a silicon-on-insulator substrate.

14. The integrated system of claim 1 wherein an active circuit of the plurality of active circuits is selected from the group consisting of a power amplifier, a low noise amplifier, a matching network, and a switch.

15. An integrated system comprising:
an active die, the active die comprising a semiconductor substrate, the active die comprising a plurality of active circuits;
an interposer, having a die side and a package substrate side, the die side opposite the package substrate side, the active die electrically coupled to the die side of the interposer, the interposer comprising an acoustic wave resonator (AWR); and
a package substrate, the package substrate having an interposer side and a land side opposite the interposer side, the interposer side of the package substrate electrically coupled to the interposer.

16. The integrated system of claim 15 further comprising a seal frame attached to the die side of the package substrate and to the active die, the seal frame surrounding the acoustic wave resonator and hermetically sealing the acoustic wave resonator in a cavity.

17. The integrated system of claim 15 further comprising a plurality of solder balls on the land side of the package substrate.

18. The integrated system of claim 15 wherein the package substrate is a multilayer package substrate, and wherein an inductor is disposed in the multilayer package substrate.

19. The integrated system of claim 15 wherein the package substrate is a multilayer package substrate, and wherein a transformer is disposed in the multilayer package substrate.

20. The integrated system of claim 15 further comprising one of a discrete inductor or a discrete capacitor attached to the package substrate.

21. An integrated system comprising:
a first active die, the first active die comprising a first semiconductor substrate, the first active die comprising a plurality of first active circuits;
a second active die, the second active die comprising a second semiconductor substrate, the second active die comprising a plurality of second active circuits; and
an interposer comprising a first acoustic wave resonator (AWR) and a second acoustic wave resonator (AWR) wherein the first active die is disposed over and electrically coupled to the first acoustic wave resonator and wherein the second active die is over and electrically coupled to the second acoustic wave resonator.

22. The integrated system of claim 21 wherein the first semiconductor substrate is a different semiconductor than the second semiconductor substrate.

23. The integrated system of claim 21 wherein the first active die comprises a receiver and wherein the second active die comprise a transmitter.

24. The integrated system of claim 21 wherein a first seal frame attaches the first active die to the interposer, the first seal frame surrounding the first acoustic wave resonator and hermetically sealing the first acoustic wave resonator between the first active die and the interposer; and
a second seal frame attaches the second active die to the interposer, the second seal frame surrounding the second acoustic wave resonator and hermetically sealing the second acoustic wave resonator between the second active die and the interposer.

25. The integrated system of claim 21 further comprising a first electromagnetic shield disposed on the first active die and a second electromagnetic shield disposed on the second active die.
